(19) United States
(12) Patent Application Publication
(10) Pub. No.: US 2022/0005678 A1
(43) Pub. Date: Jan. 6, 2022

(54) SUBSTRATE PROCESSING APPARATUS, REFLECTOR AND METHOD OF MANUFACTURING SEMICONDUCTOR DEVICE

(71) Applicant: KOKUSAI ELECTRIC CORPORATION, Tokyo (JP)

(72) Inventors: Tetsuaki INADA, Toyama (JP); Takeshi YASUI, Toyama (JP)

(73) Assignee: KOKUSAI ELECTRIC CORPORATION, Tokyo (JP)

(21) Appl. No.: 17/475,407

(22) Filed: Sep. 15, 2021

Related U.S. Application Data
(63) Continuation of application No. PCT/JP2019/011875, filed on Mar. 20, 2019.

(51) Int. Cl. H01J 37/32; H01L 21/02; C23C 8/12

(52) U.S. Cl. CPC H01J 37/32724; C23C 8/12; H01J 37/3244; H01L 21/02236

(57) ABSTRACT

Described herein is a technique capable of improving a heating efficiency for a substrate to be heated by a heater. According to one aspect of the technique of the present disclosure, there is provided a substrate processing apparatus including: a process vessel defining a process chamber; a process gas supplier configured to supply a process gas into the process vessel; an electromagnetic field generation electrode extending along an outer peripheral surface of the process vessel while being spaced apart from the outer peripheral surface of the process vessel and configured to generate an electromagnetic field in the process vessel by being supplied with a high frequency power; a heater configured to radiate an infrared light to heat a substrate accommodated in the process chamber; and a reflector provided between the process vessel and the electromagnetic field generation electrode and configured to reflect the infrared light radiated from the heater.

### CROSS-REFERENCE TO RELATED PATENT APPLICATION

This application is a Bypass Continuation Application of PCT International Application No. PCT/JP2019/011875, filed on Mar. 20, 2019, in the WIPO, the entire contents of which are hereby incorporated by reference.

### FIELD

The present disclosure relates to a substrate processing apparatus, a reflector and a method of manufacturing a semiconductor device.

### DESCRIPTION OF THE RELATED ART

When forming a pattern of a semiconductor device such as a flash memory, a predetermined process such as an oxidation process and a nitridation process, which is a part of manufacturing processes of the semiconductor device, may be performed on a substrate.

For example, according to some related arts, a surface of the pattern formed on the substrate may be modified by performing a modification process by using a process gas excited by a plasma.

When a process vessel in which the process described above is performed is made of a material whose transmittance with respect to an infrared light is high, the infrared light radiated from a component such as a heater configured to heat the substrate may be transmitted and leak out of the process vessel. Further, when the process vessel is made of a material whose absorptance with respect to the infrared light is high, most of the infrared light emitted from the heater or the substrate may be absorbed by the process vessel. In each case described above, it may be difficult to efficiently heat the substrate with the heater.

### SUMMARY

Described herein is a technique capable of improving a heating efficiency for a substrate to be heated by a heater of a substrate processing apparatus.

According to one aspect of the technique of the present disclosure, there is provided a substrate processing apparatus including: a process vessel defining a process chamber; a process gas supplier configured to supply a process gas into the process vessel; an electromagnetic field generation electrode extending along an outer peripheral surface of the process vessel while being spaced apart from the outer peripheral surface of the process vessel and configured to generate an electromagnetic field in the process vessel by being supplied with a high frequency power; a heater configured to radiate an infrared light to heat a substrate accommodated in the process chamber; and a reflector provided between the process vessel and the electromagnetic field generation electrode and configured to reflect the infrared light radiated from the heater.

### BRIEF DESCRIPTION OF THE DRAWINGS

FIG. 1 is a diagram schematically illustrating a cross-section of a substrate processing apparatus according to a first embodiment described herein.

FIG. 2 is a diagram schematically illustrating a principle of generating a plasma in the substrate processing apparatus according to the first embodiment described herein.

FIG. 3 is a block diagram schematically illustrating a configuration of a controller (control structure) and related components of the substrate processing apparatus according to the first embodiment described herein.

FIG. 4 is a flow chart schematically illustrating a substrate processing according to the first embodiment described herein.

FIG. 5 is a diagram schematically illustrating a cross-section of a substrate processing apparatus according to a second embodiment described herein.

FIG. 6 is a diagram schematically illustrating a cross-section of a substrate processing apparatus according to a third embodiment described herein.

FIG. 7 is a diagram schematically illustrating a cross-section of a substrate processing apparatus according to a fourth embodiment described herein.

### DETAILED DESCRIPTION

Hereinafter, embodiments according to the technique of the present disclosure will be described with reference to the drawings.

### First Embodiment

(1) Configuration of Substrate Processing Apparatus

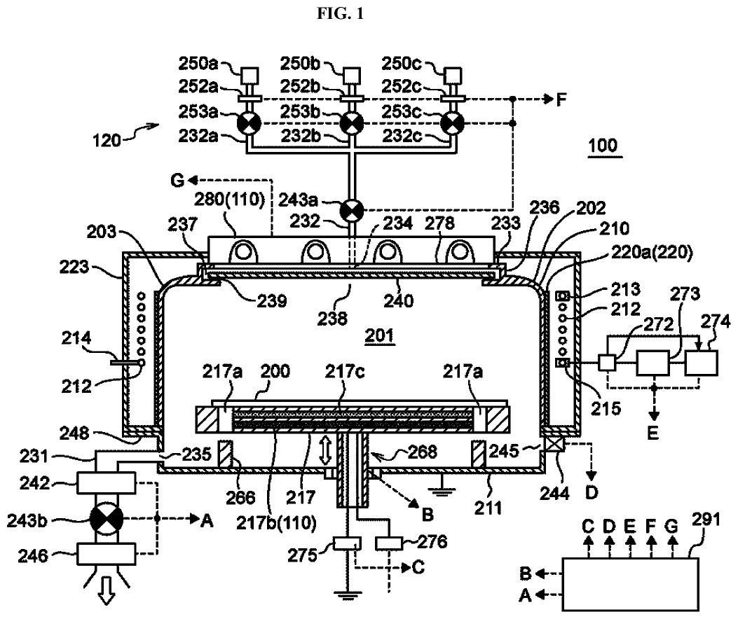

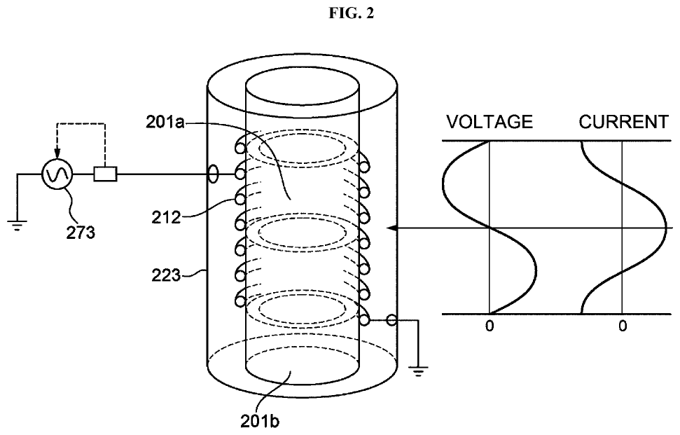

A substrate processing apparatus according to a first embodiment of the technique will be described below with reference to FIGS. 1 and 2. The substrate processing apparatus according to the present embodiment is configured to mainly perform an oxidation process on a film formed on a surface of a substrate.

<Process Chamber>

A substrate processing apparatus 100 includes a process furnace 202 in which a substrate 200 is processed by a plasma. The process furnace 202 includes a process vessel 203. A process chamber 201 is defined by the process vessel 203. The process vessel 203 includes a dome-shaped upper vessel 210 serving as a first vessel and a bowl-shaped lower vessel 211 serving as a second vessel. By covering the lower vessel 211 with the upper vessel 210, the process chamber 201 is defined. The upper vessel 210 is made of a material capable of transmitting an electromagnetic wave, for example, a non-metallic material such as quartz (SiO₂) of high purity. Further, it is preferable that the upper vessel 210 is made of transparent quartz whose transmittance with respect to an infrared light is 90% or more. As a result, it is possible to suppress an amount of the infrared light reflected by a reflector 220 described later from being reflected or absorbed by the upper vessel 210. Accordingly, it is possible to further increase an amount of the infrared light supplied to the substrate 200.

For example, the lower vessel 211 is made of a material such as aluminum (Al). A gate valve 244 is provided on a lower side wall of the lower vessel 211.

The process chamber 201 includes a plasma generation space 201a (see FIG. 2) and a substrate processing space 201b (see FIG. 2) that communicates with the plasma generation space 201a and in which the substrate 200 is processed. An electromagnetic field generation electrode 212 constituted by a resonance coil is provided around the plasma generation space 201a. The plasma generation space 201a refers to a space in which the plasma is generated, for example, a space above a lower end of the electromagnetic field generation electrode 212 and below an upper end of the electromagnetic field generation electrode 212 in the process chamber 201. The substrate processing space 201b refers to a space in which the substrate 200 is processed by the plasma, for example, a space below the lower end of the electromagnetic field generation electrode 212 in the process chamber 201.

<Susceptor>

A susceptor 217 serving as a substrate support on which the substrate 200 is placed is provided at a center of a bottom portion of the process chamber 201. For example, the susceptor 217 is made of a non-metallic material such as aluminum nitride (AlN), ceramics and quartz.

The substrate 200 placed on the susceptor 217 is processed in the process chamber 201. A susceptor heater 217b serving as a heater 110 configured to radiate the infrared light so as to heat the substrate 200 accommodated in the process chamber 201 is integrally embedded in the susceptor 217. When an electric power is supplied to the susceptor heater 217b, the susceptor heater 217b is configured to heat the substrate 200 such that the surface of the substrate 200 is heated to a predetermined temperature ranging, for example, from 25° C. to 750° C. For example, the susceptor heater 217b may be constituted by a silicon carbide heater (also simply referred to as an “SiC heater”). In such a case, for example, a peak wavelength of the infrared light emitted from the SiC heater may be in the vicinity of 5 μm.

An impedance adjustment electrode 217c is provided in the susceptor 217 so as to further improve a uniformity of a density of the plasma generated on the substrate 200 placed on the susceptor 217. The impedance adjustment electrode 217c is grounded via a variable impedance regulator 275 serving as an impedance adjusting structure. By the variable impedance regulator 275, it is possible to control a potential (bias voltage) of the substrate 200 via the impedance adjustment electrode 217c and the susceptor 217.

A susceptor elevator 268 including a driver (which is a driving structure) configured to elevate and lower the susceptor 217 is provided at the susceptor 217. Through-holes 217a are provided at the susceptor 217, and substrate lift pins 266 are provided at a bottom of the lower vessel 211 corresponding to the through-holes 217a. For example, at least three of the through-holes 217a and at least three of the substrate lift pins 266 are provided at positions facing each other. When the susceptor 217 is lowered by the susceptor elevator 268, the substrate lift pins 266 pass through the through-holes 217a, respectively.

A substrate mounting table according to the present embodiment is constituted mainly by the susceptor 217, the susceptor heater 217b and the impedance adjustment electrode 217c.

<Lamp Heater>

A light transmitting window 278 is provided above the process chamber 201, that is, on an upper surface of the upper vessel 210. A lamp heater 280 serving as the heater 110 configured to radiate the infrared light so as to heat the substrate 200 accommodated in the process chamber 201 is provided outside the light transmitting window 278 (that is, on an upper surface of the light transmitting window 278). The lamp heater 280 is provided at a location facing the susceptor 217, and is configured to heat the substrate 200 from above the substrate 200. By turning on the lamp heater 280, it is possible to elevate a temperature of the substrate 200 to a higher temperature in a shorter time as compared with a case where the susceptor heater 217b alone is used. It is preferable to use the lamp heater 280 capable of emitting a near infrared light (that is, a light whose peak wavelength preferably ranges from 800 nm to 1,300 nm, more preferably, whose peak wavelength is 1,000 nm). For example, a halogen heater may be used as the lamp heater 280 capable of emitting the near infrared light.

According to the present embodiment, both the susceptor heater 217b and the lamp heater 280 are provided as the heater 110. By using the susceptor heater 217b and the lamp heater 280 together as the heater 110 as described above, it is possible to elevate a temperature of the surface of the substrate 200 to a higher temperature, for example, about 900° C.

<Process Gas Supplier>

A process gas supplier (which is a process gas supply structure or a process gas supply system) 120 configured to supply a process gas into the process vessel 203 is configured as follows.

A gas supply head 236 is provided above the process chamber 201, that is, on an upper portion of the upper vessel 210. The gas supply head 236 includes a cap-shaped lid 233, a gas inlet port 234, a buffer chamber 237, an opening 238, a shield plate 240 and a gas outlet port 239. The gas supply head 236 is configured to supply the process gas such as a reactive gas into the process chamber 201.

An oxygen-containing gas supply pipe 232a through which oxygen gas (02 gas) serving as an oxygen-containing gas is supplied, a hydrogen-containing gas supply pipe 232b through which hydrogen gas (H₂ gas) serving as a hydrogen-containing gas is supplied and an inert gas supply pipe 232c through which argon (Ar) gas serving as an inert gas is supplied are connected to join the gas inlet port 234. An oxygen gas supply source 250a, a mass flow controller (MFC) 252a serving as a flow rate controller and a valve 253a serving as an opening/closing valve are provided at the oxygen-containing gas supply pipe 232a. A hydrogen gas supply source 250b, an MFC 252b and a valve 253b are provided at the hydrogen-containing gas supply pipe 232b. An argon gas supply source 250c, an MFC 252c and a valve 253c are provided at the inert gas supply pipe 232c. A valve 243a is provided on a downstream side of a gas supply pipe 232 at a location where the oxygen-containing gas supply pipe 232a, the hydrogen-containing gas supply pipe 232b and the inert gas supply pipe 232c join. The valve 243a is connected to the gas inlet port 234. It is possible to supply the process gas (which is a mixed gas of the oxygen-containing gas, the hydrogen-containing gas and the inert gas) into the process chamber 201 via the oxygen-containing gas supply pipe 232a, the hydrogen-containing gas supply pipe 232b and the inert gas supply pipe 232c by opening and closing the valves 253a, 253b, 253c and 243a while adjusting flow rates of the respective gases by the MFCs 252a, 252b and 252c.

The process gas supplier 120 (which is the process gas supply system) according to the present embodiment is constituted mainly by the gas supply head 236, the oxygen-containing gas supply pipe 232a, the hydrogen-containing gas supply pipe 232b, the inert gas supply pipe 232c, the MFC 252a, 252b and 252c, the valves 253a, 253b, 253c and 243a.

<Exhauster>

A gas exhaust port 235 is provided on a side wall of the lower vessel 211. An inner atmosphere of the process chamber 201 is exhausted through the gas exhaust port 235. An upstream end of a gas exhaust pipe 231 is connected to the gas exhaust port 235. An APC (Automatic Pressure Controller) 242 serving as a pressure regulator (pressure adjusting structure), a valve 243b serving as an opening/closing valve and a vacuum pump 246 serving as a vacuum exhaust apparatus are provided at the gas exhaust pipe 231.

An exhauster (which is an exhaust system) is constituted mainly by the gas exhaust port 235, the gas exhaust pipe 231, the APC 242 and the valve 243b. The exhauster may further include the vacuum pump 246.

<Plasma Generator>

The electromagnetic field generation electrode 212 constituted by the resonance coil of a helical shape is provided so as to surround the process chamber 201 around an outer periphery of the process chamber 201, that is, around an outer portion of a side wall of the upper vessel 210. An RF (Radio Frequency) sensor 272, a high frequency power supply 273 and a matcher 274 configured to perform an impedance matching or an output frequency matching for the high frequency power supply 273 are connected to the electromagnetic field generation electrode 212. The electromagnetic field generation electrode 212 extends along an outer peripheral surface of the process vessel 203 so as to be spaced apart from the outer peripheral surface of the process vessel 203, and is configured to generate an electromagnetic field in the process vessel 203 when a high frequency power (RF power) is supplied to the electromagnetic field generation electrode 212. That is, the electromagnetic field generation electrode 212 according to the present embodiment may be constituted by an inductively coupled plasma (ICP) type electrode.

The high frequency power supply 273 is configured to supply the RF power to the electromagnetic field generation electrode 212. The RF sensor 272 is provided at an output side of the high frequency power supply 273. The RF sensor 272 is configured to monitor information of the traveling wave or reflected wave of the supplied high frequency power. The reflected wave of the RF power monitored by the RF sensor 272 is input to the matcher 274, and the matcher 274 is configured to adjust an impedance of the high frequency power supply 273 or a frequency of the RF power output from the high frequency power supply 273 so as to minimize the reflected wave based on the information of the reflected wave monitored by the RF sensor 272.

A winding diameter, a winding pitch and the number of winding turns of the resonance coil serving as the electromagnetic field generation electrode 212 are set such that the electromagnetic field generation electrode 212 resonates at a constant wavelength to form a standing wave of a predetermined wavelength. That is, an electrical length of the resonance coil is set to an integral multiple of a wavelength of a predetermined frequency of the high frequency power supplied from the high frequency power supply 273.

Specifically, considering conditions such as the power to be applied, a strength of a magnetic field to be generated and a shape of an apparatus such as the substrate processing apparatus 100 to be applied to, the resonance coil (which serves as the electromagnetic field generation electrode 212) whose effective cross-section is from 50 mm² to 300 mm² and whose diameter is from 200 mm to 500 mm is wound, for example, twice to 60 times around the outer peripheral surface of the process vessel 203 defining the plasma generation space 201a such that the magnetic field of about 0.01 Gauss to about 10 Gauss can be generated by the high frequency power whose frequency is from 800 kHz to 50 MHz and whose power is from 0.5 KW to 5 KW. In the present specification, a notation of a numerical range such as “from 800 kHz to 50 MHz” means that a lower limit and an upper limit are included in the numerical range. Therefore, for example, a numerical range “from 800 kHz to 50 MHz” means a range equal to or higher than 800 kHz and equal to or less than 50 MHz. The same also applies to other numerical ranges described herein.

According to the present embodiment, for example, the frequency of the high frequency power is set to 27.12 MHz, and the electrical length of the resonance coil is set equal to the wavelength of the high frequency power (about 11 meters). For example, the winding pitch of the resonance coil is set at equal intervals of 24.5 mm. The winding diameter (diameter) of the resonance coil is set to be larger than a diameter of the substrate 200. According to the present embodiment, for example, the diameter of the substrate 200 is set to 300 mm, and the winding diameter of the resonance coil is set to 500 mm, which is larger than the diameter of the substrate 200.

For example, a copper pipe, a copper thin plate, an aluminum pipe, an aluminum thin plate, a material obtained by depositing copper or aluminum on a polymer belt may be used as a material constituting the resonance coil serving as the electromagnetic field generation electrode 212. The resonance coil is supported by a plurality of supports (not shown) made of an insulating material, which are provided on an upper end surface of a base plate 248 so as to extend vertically.

Both ends of the resonance coil serving as the electromagnetic field generation electrode 212 are electrically grounded. One end of the resonance coil is grounded via a movable tap 213 in order to fine-tune the electrical length of the resonance coil, and the other end of the resonance coil is grounded via a fixed ground 214. A position of the movable tap 213 may be adjusted in order for the resonance characteristics of the resonance coil to become approximately the same as those of the high frequency power supply 273. In addition, in order to fine-tune the impedance of the resonance coil, a power feeder (not shown) is constituted by a movable tap 215 between the grounded ends of the resonance coil.

A shield plate 223 is provided to shield an electric field outside the resonance coil serving as the electromagnetic field generation electrode 212. In general, the shield plate 223 is made of a conductive material such as an aluminum alloy, and is of a cylindrical shape. The shield plate 223 is disposed, for example, about 5 mm to 150 mm apart from an outer periphery of the resonance coil.

A plasma generator according to the present embodiment is constituted mainly by the electromagnetic field generation electrode 212, the RF sensor 272 and the matcher 274. The plasma generator may further include the high frequency power supply 273.

Hereinafter, a principle of generating the plasma in the substrate processing apparatus 100 according to the present embodiment and the properties of the generated plasma will be described with reference to FIG. 2.

A plasma generation circuit constituted by the electromagnetic field generation electrode 212 is configured as an RLC parallel resonance circuit. When the plasma is generated in the plasma generation circuit, an actual resonance frequency may fluctuate slightly depending on conditions such as a variation (change) in a capacitive coupling between a voltage portion of the resonance coil and the plasma, a variation in an inductive coupling between the plasma generation space 201a and the plasma and an excitation state of the plasma.

Therefore, according to the present embodiment, in order to compensate for a resonance shift in the resonance coil serving as the electromagnetic field generation electrode 212 when the plasma is generated by adjusting the power supplied from the high frequency power supply 273, the RF sensor 272 is configured to detect the power of the reflected wave from the resonance coil when the plasma is generated, and the matcher 274 is configured to correct the output of the high frequency power supply 273 based on the detected power of the reflected wave.

Specifically, the matcher 274 is configured to increase or decrease the impedance or the output frequency of the high frequency power supply 273 such that the power of the reflected wave is minimized based on the power of the reflected wave from the electromagnetic field generation electrode 212 detected by the RF sensor 272 when the plasma is generated.

With such a configuration, as shown in FIG. 2, the high frequency power in accordance with the actual resonance frequency of the resonance coil combined with the plasma is supplied to the electromagnetic field generation electrode 212 (or the high frequency power is supplied to match an actual impedance of the resonance coil combined with the plasma). Therefore, the standing wave in which the phase voltage thereof and the opposite phase voltage thereof are always canceled out by each other is generated in the electromagnetic field generation electrode 212. When the electrical length of the resonance coil serving as the electromagnetic field generation electrode 212 and the wavelength of the high frequency power are the same, the highest phase current is generated at an electric midpoint of the electromagnetic field generation electrode 212 (node with zero voltage). Therefore, a donut-shaped induction plasma whose electric potential is extremely low is generated in the vicinity of the electric midpoint of the electromagnetic field generation electrode 212. The donut-shaped induction plasma is hardly capacitively coupled with walls of the process chamber 201 or the susceptor 217.

The electromagnetic field generation electrode 212 is not limited to the ICP type resonance coil as described above. For example, a modified magnetron type (MMT) electrode of a cylindrical shape may be used as the electromagnetic field generation electrode 212.

<Reflector>

The reflector 220 is provided between the upper vessel 210 constituting the process vessel 203 and the electromagnetic field generation electrode 212. The reflector 220 is configured to reflect the infrared light radiated from the heater 110 and the infrared light indirectly radiated from the substrate 200. The reflector 220 according to the present embodiment is configured as a reflective film 220a capable of reflecting the infrared light, and is in contact with an outer peripheral surface of the upper vessel 210 so as to surround the entirety of the outer peripheral surface. The reflective film 220a is made of a non-metallic material capable of transmitting the electromagnetic wave and reflecting the infrared light, specifically, one or both of aluminum oxide (Al₂O₃) and yttrium oxide (Y₂O₃). The reflective film 220a is provided by forming a coating film on the outer peripheral surface of the upper vessel 210 by a spray coating process using the non-metallic material such as the Al₂O₃ and the Y₂O₃.

It is particularly preferable that the reflector 220 can reflect the infrared light whose wavelength is within a range from 0.8 μm to 100 μm. A reflectance of the reflector 220 (and the reflective film 220a) with respect to the infrared light is preferably 70% or more, and more preferably 80% or more. In addition, an absorptance of the reflector 220 (and the reflective film 220a) with respect to the infrared light is preferably 25% or less, and more preferably 15% or less. As a preferred example, the reflective film 220a is formed as a film of Al₂O₃ whose thickness is 200 μm or more. With such a configuration, it is possible to set the reflectance of the reflective film 220a with respect to the infrared light to 80% or more.

For example, the reflectance and the absorptance with respect to the infrared light in the present embodiment are values for the infrared light whose wavelength is around 1,000 nm. However, depending on parameters such as the peak wavelength of the infrared light radiated from the heater 110 and the wavelength easily absorbed by the substrate 200, the reflectance and the absorptance may be determined based on a wavelength different from 1,000 nm.

<Controller>

A controller 291 serving as a control structure is configured to individually control the APC 242, the valve 243b and the vacuum pump 246 through a signal line “A”, the susceptor elevator 268 through a signal line “B”, a heater power regulator 276 and the variable impedance regulator 275 through a signal line “C”, the gate valve 244 through a signal line “D”, the RF sensor 272, the high frequency power supply 273 and the matcher 274 through a signal line “E”, and the MFCs 252a, 252b and 252c and the valves 253a, 253b, 253c and 243a through a signal line “F”.

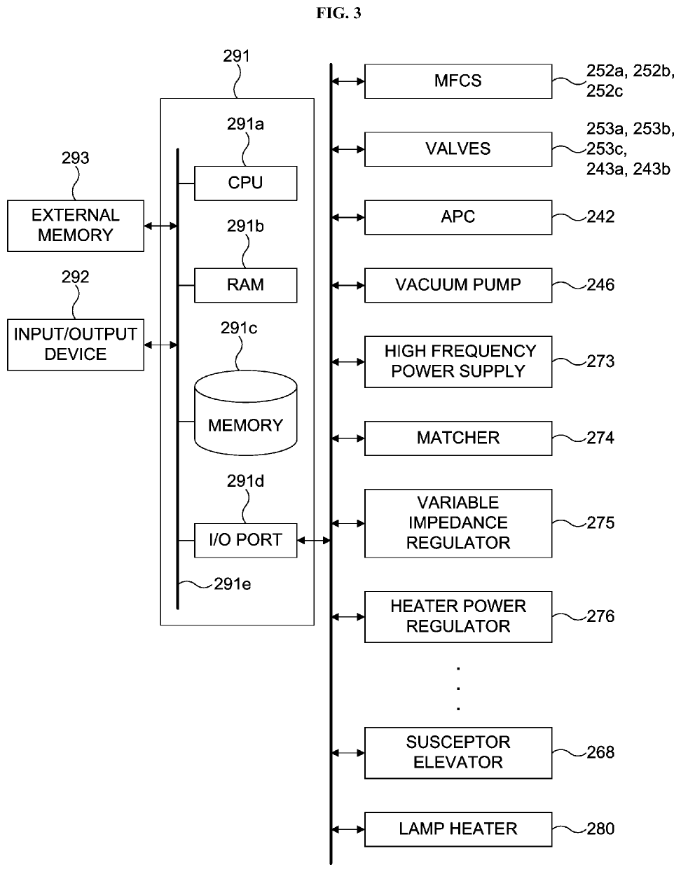

As shown in FIG. 3, the controller 291 serving as a control structure (control apparatus) is constituted by a computer including a CPU (Central Processing Unit) 291a, a RAM (Random Access Memory) 291b, a memory 291c and an I/O port 291d. The RAM 291b, the memory 291c and the I/O port 291d may exchange data with the CPU 291a through an internal bus 291e. For example, an input/output device 292 constituted by components such as a touch panel and a display may be connected to the controller 291.

The memory 291c may be embodied by a component such as a flash memory and a HDD (Hard Disk Drive). For example, a control program configured to control the operation of the substrate processing apparatus 100 and a process recipe in which information such as the sequences and the conditions of a substrate processing described later is stored may be readably stored in the memory 291c. The process recipe is obtained by combining steps of the substrate processing described later such that the controller 291 can execute the steps to acquire a predetermined result, and functions as a program. Hereinafter, the process recipe and the control program are collectively or individually referred to as a “program”. In the present specification, the term “program” may refer to the process recipe alone, may refer to the control program alone, or may refer to both of the process recipe and the control program. The RAM 291b functions as a memory area (work area) where a program or data read by the CPU 291a is temporarily stored.

The I/O port 291d is electrically connected to the above-described components such as the MFCs 252a, 252b and 252c, the valves 253a, 253b, 253c, 243a and 243b, the gate valve 244, the APC 242, the vacuum pump 246, the RF sensor 272, the high frequency power supply 273, the matcher 274, the susceptor elevator 268, the variable impedance regulator 275 and the heater power regulator 276.

The CPU 291a is configured to read and execute the control program stored in the memory 291c, and to read the process recipe stored in the memory 291c in accordance with an instruction such as an operation command inputted via the input/output device 292. The CPU 291a is configured to control the operation of the substrate processing apparatus 100 according to the read process recipe. For example, the CPU 291a may be configured to perform the operation, according to the read process recipe, such as an operation of adjusting an opening degree of the APC 242, an opening and closing operation of the valve 243b and a start and stop of the vacuum pump 246 via the I/O port 291d and the signal line “A”, an elevating and lowering operation of the susceptor elevator 268 via the I/O port 291d and the signal line “B”, a power supply amount adjusting operation (temperature adjusting operation) to the susceptor heater 217b by the heater power regulator 276 and an impedance adjusting operation by the variable impedance regulator 275 via the I/O port 291d and the signal line “C”, an opening and closing operation of the gate valve 244 via the I/O port 291d and the signal line “D”, a controlling operation of the RF sensor 272, the matcher 274 and the high frequency power supply 273 via the I/O port 291d and the signal line “E”, and gas flow rate adjusting operations of the MFCs 252a, 252b and 252c and opening and closing operations of the valves 253a, 253b, 253c and 243a via the I/O port 291d and the signal line “F”.

The controller 291 may be embodied by installing the above-described program stored in an external memory 293 into a computer. The memory 291c or the external memory 293 may be embodied by a non-transitory computer readable recording medium. Hereafter, the memory 291c and the external memory 293 are collectively or individually referred to as a “recording medium”. In the present specification, the term “recording medium” may refer to the memory 291c alone, may refer to the external memory 293 alone, and may refer to both of the memory 291c and the external memory 293. Instead of the external memory 293, a communication means such as the Internet and a dedicated line may be used for providing the program to the computer.

(2) Substrate Processing

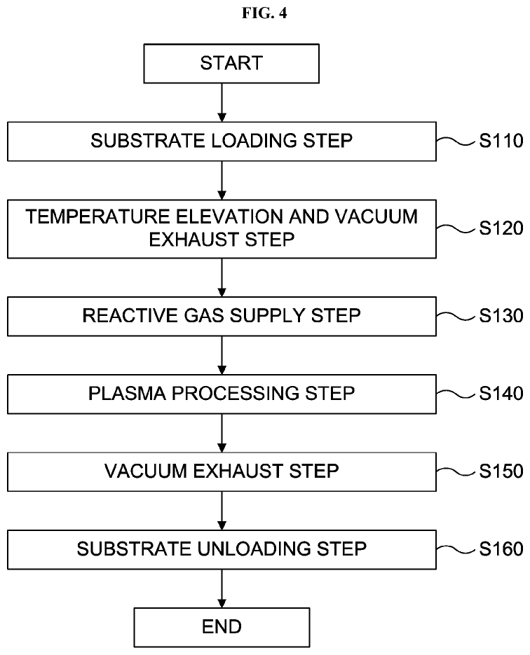

Subsequently, the substrate processing according to the present embodiment will be described mainly with reference to FIG. 4. FIG. 4 is a flow chart schematically illustrating the substrate processing according to the present embodiment. The substrate processing according to the present embodiment, which is a part of manufacturing processes of a semiconductor device such as a flash memory, is performed by the substrate processing apparatus 100 described above. In the following description, the operations of the components constituting the substrate processing apparatus 100 are controlled by the controller 291.

A silicon layer is formed in advance on the surface of the substrate 200 to be processed in the substrate processing according to the present embodiment. In the present embodiment, for example, the oxidation process serving as a process using the plasma is performed on the silicon layer.

<Substrate Loading Step S110>

First, the susceptor 217 is lowered to a position of transferring the substrate 200 by the susceptor elevator 268 such that the substrate lift pins 266 pass through the through-holes 217a of the susceptor 217. Subsequently, the gate valve 244 is opened, and the substrate 200 is transferred (loaded) into the process chamber 201 using a substrate transfer device (not shown) from a vacuum transfer chamber (not shown) provided adjacent to the process chamber 201. The substrate 200 loaded into the process chamber 201 is supported in a horizontal orientation by the substrate lift pins 266 protruding from a surface of the susceptor 217. Thereafter, the susceptor elevator 268 elevates the susceptor 217 until the substrate 200 is placed on an upper surface of the susceptor 217 and supported by the susceptor 217.

<Temperature Elevation and Vacuum Exhaust Step S120>

Subsequently, the temperature of the substrate 200 loaded into the process chamber 201 is elevated. In the step S120, the susceptor heater 217b is heated in advance, and by turning on (ON) the lamp heater 280, for example, the substrate 200 placed on the susceptor 217 is heated to a predetermined temperature within a range from 700° C. to 900° C. In the step S120, for example, the substrate 200 is heated such that the temperature of the substrate 200 reaches and is maintained at 800° C. In the step S120, the infrared light radiated from the susceptor heater 217b and the lamp heater 280 that heat the substrate 200 and the infrared light radiated from the substrate 200 heated by the susceptor heater 217b and the lamp heater 280 may pass through the upper vessel 210. However, most of the heat is reflected back into the process vessel 203 by the reflective film 220a serving as the reflector 220 provided in contact with the outer peripheral surface of the upper vessel 210 without being absorbed, and then is absorbed by the substrate 200. Thereby, it is possible to efficiently heat the substrate 200 by the heat reflected back into the process vessel 203. Further, while the substrate 200 is being heated, the vacuum pump 246 vacuum-exhausts an inner atmosphere of the process chamber 201 through the gas exhaust pipe 231 such that the inner pressure of the process chamber 201 reaches and is maintained at a predetermined pressure. The vacuum pump 246 vacuum-exhausts the inner atmosphere of the process chamber 201 at least until a substrate unloading step S160 described later is completed.

<Reactive Gas Supply Step S130>

Subsequently, the O₂ gas (which is the oxygen-containing gas) and the H₂ gas (which is the hydrogen-containing gas) are supplied into the process chamber 201 as the reactive gas. Specifically, the valves 253a and 253b are opened to supply the O₂ gas and the H₂ gas, respectively, into the process chamber 201 while flow rates of the O₂ gas and the H₂ gas are adjusted by the MFCs 252a and 252b, respectively.

In the reactive gas supply step S130, the inner atmosphere of the process chamber 201 is exhausted by adjusting the opening degree of the APC 242 such that the inner pressure of the process chamber 201 reaches and is maintained at a predetermined pressure. The O₂ gas and the H₂ gas are continuously supplied into the process chamber 201 until a plasma processing step S140 described later is completed.

<Plasma Processing Step S140>

When the inner pressure of the process chamber 201 is stabilized, the high frequency power is supplied to the electromagnetic field generation electrode 212 from the high frequency power supply 273. Thereby, a high frequency electric field is formed in the plasma generation space 201a to which the O₂ gas and the H₂ gas are supplied, and the donut-shaped induction plasma whose plasma density is the highest is excited by the high frequency electric field at a height corresponding to the electric midpoint of the electromagnetic field generation electrode 212 in the plasma generation space 201a. The process gas such as the O₂ gas and the H₂ gas are plasma excited and dissociate. As a result, reactive species such as oxygen radicals containing oxygen (oxygen active species), oxygen ions, hydrogen radicals containing hydrogen (hydrogen active species) and hydrogen ions may be generated.

The radicals generated by the induction plasma and non-accelerated ions are uniformly supplied onto the surface of the substrate 200 placed on the susceptor 217 in the substrate processing space 201b. Then, the radicals and the ions uniformly supplied onto the surface of the substrate 200 uniformly react with the silicon layer formed on the surface of the substrate 200. Thereby, the silicon layer is modified into a silicon oxide layer whose step coverage is good.

After a predetermined process time has elapsed (for example, 10 seconds to 300 seconds), the supply of the high frequency power from the high frequency power supply 273 is stopped to stop a plasma discharge in the process chamber 201. In addition, the valves 253a and 253b are closed to stop the supply of the O₂ gas and the supply of the H₂ gas into the process chamber 201. Thereby, the plasma processing step S140 is completed.

<Vacuum Exhaust Step S150>

After the supply of the O₂ gas and the supply of the H₂ gas are stopped, the inner atmosphere of the process chamber 201 is vacuum-exhausted through the gas exhaust pipe 231. Thereby, the gas such as the O₂ gas and the H₂ gas in the process chamber 201 is exhausted outside of the process chamber 201. Thereafter, the opening degree of the APC 242 is adjusted such that the inner pressure of the process chamber 201 is adjusted to the same pressure as that of the vacuum transfer chamber (not shown) provided adjacent to the process chamber 201.

<Substrate Unloading Step S160>

After the inner pressure of the process chamber 201 is adjusted to a predetermined pressure, the susceptor 217 is lowered to the position of transferring the substrate 200 until the substrate 200 is supported by the substrate lift pins 266. Then, the gate valve 244 is opened, and the substrate 200 is transferred (unloaded) out of the process chamber 201 by using the substrate transfer device (not shown). Thereby, the substrate processing according to the present embodiment is completed.

According to the present embodiment described above, by reflecting the infrared light radiated from the heater 110 so as to be confined inside the electromagnetic field generation electrode 212 (that is, inside the process vessel 203), a density of the infrared light radiated to the substrate 200 can be increased. Thus, it is possible to improve a heating efficiency of the substrate 200. That is, it is possible to achieve effects such as elevating the temperature of the substrate 200, improving a temperature elevation rate, and energy saving. Further, in particular, since the reflector 220 is arranged between the electromagnetic field generation electrode 212 and the upper vessel 210 constituting the process vessel 203, as compared with a case in which the reflector 220 is arranged outside the electromagnetic field generation electrode 212, it is possible to reflect the infrared light inward without being shielded and absorbed by the electromagnetic field generation electrode 212. Therefore, it is possible to improve the heating efficiency by reflecting the infrared light radiated from the heater 110 inward more efficiently.

As in the present embodiment, when the substrate 200 is heated by the susceptor heater 217b serving as the heater 110, the infrared light radiated from the susceptor heater 217b is reflected toward an inside of the process vessel 203 so as to obtain the effects described above such as elevating the temperature of the substrate 200, improving the temperature elevation rate and energy saving in addition to improving the heating efficiency.

As in the present embodiment, when the lamp heater 280 is provided in addition to the susceptor heater 217b as the heater 110 and the substrate 200 is heated by both the susceptor heater 217b and the lamp heater 280, the infrared light radiated from both the susceptor heater 217b and the lamp heater 280 is reflected toward the inside of the process vessel 203 so as to remarkably enhance the effects described above such as elevating the temperature of the substrate 200, improving the temperature elevation rate and energy saving in addition to improving the heating efficiency.

As described above, since each of the upper vessel 210 and the reflector 220 is made of a material capable of transmitting the electromagnetic wave, particularly a non-metallic material, the electromagnetic wave generated from the electromagnetic field generation electrode 212 is transmitted through the reflector 220 and the upper vessel 210. Therefore, it is possible to excite the process gas in the process chamber 201 by the plasma without being disturbed by the upper vessel 210 and the reflector 220.

As described above, by forming the reflective film 220a serving as the reflector 220 on the outer peripheral surface of the upper vessel 210, it is possible to reflect the infrared light radiated from the heater 110 so as to be confined inside the process vessel 203 by the reflective film 220a. Therefore, it is possible to more remarkably improve the heating efficiency of the substrate 200.

On the other hand, when forming the reflective film 220a inside the upper vessel 210 which is in a vacuum state, the reflective film 220a may be peeled off by the plasma and become a foreign substance on the substrate 200. Thereby, a substrate manufacturing yield may deteriorate. Therefore, by forming the reflective film 220a on the outer peripheral surface of the upper vessel 210, it is possible to prevent the inside of the process vessel 203 from being contaminated by the peeled-off portion of the reflective film 220a or the material constituting the reflective film 220a. Further, when cleaning the upper vessel 210, it is possible to selectively clean an inside of the upper vessel 210 alone without removing the reflective film 220a.

Since the reflective film 220a is made of one or both of the Al₂O₃ and the Y₂O₃, it is possible to reflect the infrared light (which is transmitted from the process chamber 201 through the upper vessel 210) back into the process chamber 201 without disturbing the transmission of the electromagnetic wave generated by the electromagnetic field generation electrode 212.

Further, by setting the thickness of the reflective film 220a to 200 μm or more, it is possible to set the reflectance of the reflective film 220a with respect to the infrared light to 80% or more. By setting the reflectance of the reflective film 220a to 80% or more, it is possible to remarkably obtain the effects described above such as elevating the temperature of the substrate 200. Further, by setting the absorptance of the reflective film 220a with respect to the infrared light to 15% or less, it is possible to prevent the temperatures of the reflective film 220a and the process vessel 203 in contact with the reflective film 220a from elevating excessively, and it is also possible to prevent (or suppress) components provided around the process vessel 203 (for example, a component made of a resin material such as an O-ring) from being deteriorated by the heat. In addition, according to the present embodiment, the upper vessel 210 is made of quartz whose thermal conductivity is relatively low, and the reflective film 220a whose heat capacity is smaller than the upper vessel 210 and whose thickness is thinner than the upper vessel 210 is provided on the outer peripheral surface of the upper vessel 210. Therefore, even when the reflector 220 is made of the Al₂O₃ whose thermal conductivity or absorptance with respect to the infrared light is relatively high, it is possible to prevent (or suppress) the temperature of the upper vessel 210 from elevating excessively.

When the metal is used as the material of the reflective film 220a, the electromagnetic wave is shielded and the plasma is not excited in the process vessel 203. Therefore, the metal is not suitable for the material of the reflective film 220a.

Further, since the reflector 220 is provided so as to surround the entirety of the outer peripheral surface of the upper vessel 210 (that is, a transparent portion of the process vessel 203) facing the electromagnetic field generation electrode 212, it is possible to block both of the transmission and the leakage of the infrared light from a side wall of the process vessel 203. Therefore, it is possible to remarkably enhance the effect described above such as confining the infrared light in the process vessel 203. In addition, by suppressing the radiation of the infrared light to the electromagnetic field generation electrode 212, it is possible to remarkably enhance an effect of suppressing a temperature elevation of the electromagnetic field generation electrode 212 and its periphery.

### Second Embodiment

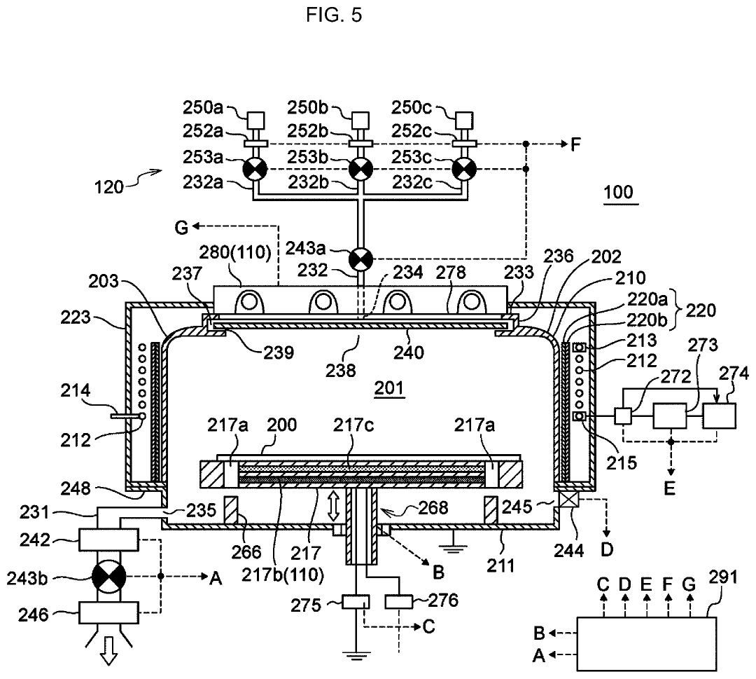

FIG. 5 is a diagram schematically illustrating the substrate processing apparatus 100 according to a second embodiment of the technique. According to the present embodiment, a configuration of the reflector 220 is different from that of the first embodiment. However, other configurations of the present embodiment are the same as those of the first embodiment.

When the upper vessel 210 is repeatedly used, an inner surface of the upper vessel 210 may be contaminated. When the inner surface of the upper vessel 210 is contaminated, the upper vessel 210 may be removed, washed and reused. In such a case, in the upper vessel 210 of the first embodiment, since the reflective film 220a is provided in contact with the outer peripheral surface of the upper vessel 210, the reflective film 220a may be peeled off by cleaning the upper vessel 210, and the reflectance of the reflective film 220a may deteriorate when the upper vessel 210 is reused.

Therefore, according to the present embodiment, the reflector 220 is provided between the upper vessel 210 and the electromagnetic field generation electrode 212 so as to surround the outer peripheral surface of the upper vessel 210 while being spaced apart from the outer peripheral surface of the upper vessel 210. The reflector 220 is constituted by a support cylinder 220b and the reflective film 220a in contact with an inner peripheral surface of the support cylinder 220b. The support cylinder 220b of a cylindrical shape is made of a non-metallic material capable of transmitting the electromagnetic wave, specifically quartz. Further, as in the first embodiment, the reflective film 220a is made of the non-metallic material capable of transmitting the electromagnetic wave and reflecting the infrared light, specifically, one or both of the Al₂O₃ and the Y₂O₃. The reflective film 220a is provided by forming a coating film on the inner peripheral surface of the support cylinder 220b by a spray coating process using the non-metallic material such as the Al₂O₃ and the Y₂O₃. Preferably, the reflective film 220a is formed as the film of Al₂O₃ whose thickness is 200 μm or more. With such a configuration, according to the present embodiment, it is possible to set the reflectance of the reflective film 220a with respect to the infrared light to 80% or more.

In the substrate processing apparatus 100 according to the present embodiment, as in the first embodiment, the substrate 200 is processed by each step shown in FIG. 4, and the semiconductor device is manufactured.

In particular, in the temperature elevation and vacuum exhaust step S120 according to the present embodiment, the temperature of the substrate 200 loaded into the process chamber 201 is elevated. Specifically, the substrate 200 placed on the susceptor 217 is heated to a predetermined temperature by the susceptor heater 217b and the lamp heater 280. In the step S120 according to the present embodiment, the infrared light radiated from the susceptor heater 217b and the lamp heater 280 that heat the substrate 200 and the infrared light radiated from the substrate 200 heated by the susceptor heater 217b and the lamp heater 280 may pass through the upper vessel 210. However, most of the heat is reflected back into the process vessel 203 by the reflective film 220a on the inner peripheral surface of the support cylinder 220b (which is provided so as to surround the outer peripheral surface of the upper vessel 210) without being absorbed, and then is absorbed by the substrate 200. Thereby, it is possible to efficiently heat the substrate 200 by the heat reflected back into the process vessel 203.

According to the present embodiment described above, by inserting the support cylinder 220b on which the reflective film 220a is provided as described above instead of, for example, coating the reflective film 220a directly on the outer peripheral surface of the upper vessel 210, it is possible to reflect the infrared light radiated from the heater 110 toward the inside of the process vessel 203 so as to be confined inside the process vessel 203. Further, by providing the support cylinder 220b outside the process vessel 203, it is possible to prevent the inside of the process vessel 203 from being contaminated by the peeled-off portion of the reflective film 220a or the material constituting the reflective film 220a. Further, when cleaning the upper vessel 210, it is possible to eliminate a process such as a process of peeling off the reflective film 220a. In addition, since the reflective film 220a can be provided on the support cylinder 220b of a simple cylindrical shape, it is possible to more easily provide the upper vessel 210 as compared with a case where the reflective film 220a is provided on the outer peripheral surface of the upper vessel 210. Further, when the support cylinder 220b is made of quartz, it is sufficient to form the reflective film 220a with a reflective material alone. Therefore, it is possible to reduce a manufacturing cost and a difficulty of manufacturing the support cylinder 220b as compared with a case where the entirety of the support cylinder 220b is made of the reflective material.

Further, by providing the reflective film 220a on the inner peripheral surface of the support cylinder 220b, the infrared light radiated from the inside of the process chamber 201 is reflected back into the process chamber 201 by the reflective film 220a before reaching the support cylinder 220b. Therefore, it is possible to suppress the generation of a heat absorption by the support cylinder 220b. Thereby, it is possible to further improve the heating efficiency. In order to suppress the generation of the heat absorption by the support cylinder 220b, it is preferable that the support cylinder 220b is made of a material such as transparent quartz capable of easily transmitting the infrared light. However, when the reflective film 220a is provided on the inner peripheral surface of the support cylinder 220b, it is possible to achieve the same effects described above even when the support cylinder 220b is made of a material that hardly transmits the infrared light.

Conditions of the present embodiment such as the material and the thickness of the reflective film 220a and the reflectance and the absorptance of the reflective film 220a with respect to the infrared light may be set to be the same as those of the first embodiment. Even in such a case, it is possible to achieve the same effects as those of the first embodiment.

### Third Embodiment

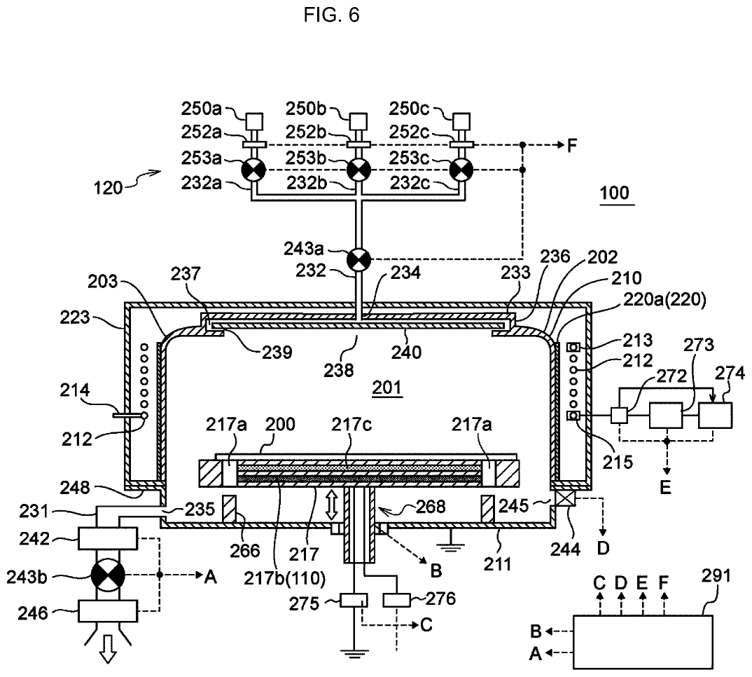

FIG. 6 is a diagram schematically illustrating the substrate processing apparatus 100 according to a third embodiment of the technique. The present embodiment is different from the first embodiment in that the lamp heater 280 serving as the heater 110 is not provided and the susceptor heater 217b alone serves as the heater 110. However, other configurations of the present embodiment are the same as those of the first embodiment, including the reflective film 220a serving as the reflector 220 provided in contact with the outer peripheral surface of the upper vessel 210.

In the substrate processing apparatus 100 according to the present embodiment, as in the first embodiment, the substrate 200 is processed by each step shown in FIG. 4, and the semiconductor device is manufactured.

In particular, in the temperature elevation and vacuum exhaust step S120 according to the present embodiment, the temperature of the substrate 200 loaded into the process chamber 201 is elevated. Specifically, the substrate 200 placed on the susceptor 217 is heated to a predetermined temperature within a range from 150° C. to 750° C. by the susceptor heater 217b. In the step S120 according to the present embodiment, for example, the substrate 200 is heated such that the temperature of the substrate 200 reaches and is maintained at 600° C. In the step S120 according to the present embodiment, the infrared light radiated from the susceptor heater 217b that heats the substrate 200 and the infrared light radiated from the substrate 200 heated by the susceptor heater 217b may pass through the process vessel 203. However, most of the heat is reflected back into the process vessel 203 by the reflective film 220a serving as the reflector 220 in contact with the outer peripheral surface of the process vessel 203 without being absorbed, and then is absorbed by the substrate 200. Thereby, it is possible to efficiently heat the substrate 200 by the heat reflected back into the process vessel 203.

### Fourth Embodiment

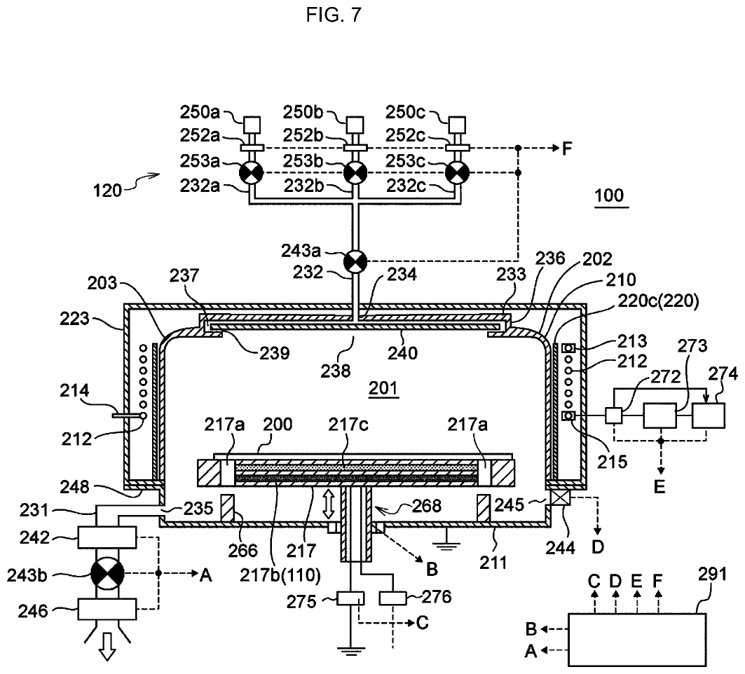

FIG. 7 is a diagram schematically illustrating the substrate processing apparatus 100 according to a fourth embodiment of the technique. The present embodiment is different from the first embodiment in that the lamp heater 280 serving as the heater 110 is not provided and the susceptor heater 217b alone serves as the heater 110 and that a configuration of the reflector 220 is different from that of the first embodiment. However, other configurations of the present embodiment are the same as those of the first embodiment.

According to the present embodiment, the reflector 220 is provided between the process vessel 203 and the electromagnetic field generation electrode 212 so as to surround the outer peripheral surface of the process vessel 203 while being spaced apart from the outer peripheral surface of the process vessel 203. The reflector 220 is constituted by a reflective cylinder 220c of a cylindrical shape made of a non-metallic material capable of transmitting the electromagnetic wave and reflecting the infrared light, specifically, one or both of the Al₂O₃ and the Y₂O₃. It is preferable that the entirety of the reflective cylinder 220c is made of one or both of the Al₂O₃ and the Y₂O₃.

More preferably, the reflective cylinder 220c is constituted by a cylinder made of the Al₂O₃ whose thickness is of 200 μm or more. By providing the reflective cylinder 220c as described above, it is possible to set the reflectance of the reflective cylinder 220c with respect to the infrared light to 80% or more. However, in order to secure a mechanical strength of the reflective cylinder 220c, it is preferable that the thickness of the reflective cylinder 220c is 10 mm or more in practical use.

In the substrate processing apparatus 100 according to the present embodiment, as in the first embodiment, the substrate 200 is processed by each step shown in FIG. 4, and the semiconductor device is manufactured.

In particular, in the temperature elevation and vacuum exhaust step S120 according to the present embodiment, the temperature of the substrate 200 loaded into the process chamber 201 is elevated. Specifically, the substrate 200 placed on the susceptor 217 is heated to a predetermined temperature by the susceptor heater 217b as in the third embodiment. In the step S120 according to the present embodiment, the infrared light radiated from the susceptor heater 217b that heat the substrate 200 and the infrared light radiated from the substrate 200 heated by the susceptor heater 217b may pass through the process vessel 203. However, most of the heat is reflected back into the process vessel 203 by the reflective cylinder 220c extending along the outer peripheral surface of the process vessel 203 without being absorbed in an inner surface of the reflective cylinder 220c, and then is absorbed by the substrate 200. Thereby, it is possible to efficiently heat the substrate 200 by the heat reflected back into the process vessel 203.

According to the present embodiment described above, by inserting the reflective cylinder 220c made of the non-metallic material capable of reflecting the infrared light as described above instead of, for example, coating the reflective film 220a directly on the outer peripheral surface of the process vessel 203, it is possible to reflect the infrared light radiated from the heater 110 toward the inside of the process vessel 203 so as to be confined inside the process vessel 203. Further, by providing the reflective cylinder 220c outside the process vessel 203, it is possible to prevent the inside of the process vessel 203 from being contaminated by the peed-off portion of the reflective film 220a or the material constituting the reflective film 220a. Further, when cleaning the process vessel 203, it is possible to eliminate the process such as the process of peeling off the reflective film 220a. In addition, since the reflective cylinder 220c of a simple cylindrical shape made of the non-metallic material capable of reflecting the infrared light can be provided, it is possible to more easily provide the process vessel 203 as compared with a case where the reflective film 220a is provided on the outer peripheral surface of the process vessel 203. Further, since the entirety of the reflective cylinder 220c of a cylindrical shape is made of the non-metallic material capable of reflecting the infrared light, it is possible to further increase the reflectance of the reflective cylinder 220c.

### Other Embodiments

While the technique of the present disclosure is described in detail by way of the embodiments described above, the above-described technique is not limited thereto. The above-described technique may be modified in various ways without departing from the scope thereof. For example, the embodiments described above are described by way of an example in which the plasma is used to perform the process such as the oxidation process and a nitridation process on the surface of the substrate, the above-described technique is not limited thereto. For example, the above-described technique may also be applied to other processes using the plasma to process the substrate. For example, the above-described technique may be applied to other processes using the plasma such as a modification process (or a doping process) on the film formed on the surface of the substrate, a reduction process of an oxide film, an etching process of the film and an ashing process of a photoresist.

As described above, according to some embodiments in the present disclosure, it is possible to improve the heating efficiency for the substrate to be heated by the heater of the substrate processing apparatus. Thereby, it is possible to shorten the substrate processing time to improve the productivity, and also possible to form the film whose quality is high by increasing the temperature of the substrate processing.

What is claimed is:

1. A substrate processing apparatus comprising:
a process vessel defining a process chamber;
a process gas supplier configured to supply a process gas into the process vessel;
an electromagnetic field generation electrode extending along an outer peripheral surface of the process vessel while being spaced apart from the outer peripheral surface of the process vessel and configured to generate an electromagnetic field in the process vessel by being supplied with a high frequency power;
a heater configured to radiate an infrared light to heat a substrate accommodated in the process chamber; and
a reflector provided between the process vessel and the electromagnetic field generation electrode and configured to reflect the infrared light radiated from the heater.

2. The substrate processing apparatus of claim 1, wherein the heater comprises a susceptor heater provided in a susceptor configured to support the substrate in the process chamber.

3. The substrate processing apparatus of claim 1, wherein the heater comprises a lamp heater.

4. The substrate processing apparatus of claim 1, wherein each of the process vessel and the reflector is made of a material capable of transmitting an electromagnetic wave.

5. The substrate processing apparatus of claim 4, wherein the material capable of transmitting the electromagnetic wave comprises a non-metallic material.

6. The substrate processing apparatus of claim 1, wherein the reflector comprises
a reflective film capable of reflecting the infrared light and provided in contact with the outer peripheral surface of the process vessel.

7. The substrate processing apparatus of claim 1, wherein the reflector comprises:
a support cylinder provided so as to surround the outer peripheral surface of the process vessel while being spaced apart from the outer peripheral surface of the process vessel; and
a reflective film provided in contact with a surface of the support cylinder and configured to reflect the infrared light.

8. The substrate processing apparatus of claim 7, wherein the reflective film is provided in contact with an inner peripheral surface of the support cylinder.

9. The substrate processing apparatus of claim 6, wherein the reflective film is made of one or both of aluminum oxide and yttrium oxide.

10. The substrate processing apparatus of claim 7, wherein the reflective film is made of one or both of aluminum oxide and yttrium oxide.

11. The substrate processing apparatus of claim 1, wherein the reflector comprises:
a reflective cylinder provided so as to surround the outer peripheral surface of the process vessel while being spaced apart from the outer peripheral surface of the process vessel and made of a material capable of reflecting the infrared light.

12. The substrate processing apparatus of claim 1, wherein the reflector is provided so as to surround an entirety of the outer peripheral surface of the process vessel.

13. The substrate processing apparatus of claim 1, wherein the electromagnetic field generation electrode is configured to plasma-excite the process gas in the process vessel by the electromagnetic field generated in the process vessel.

14. The substrate processing apparatus of claim 12, wherein the electromagnetic field generation electrode comprises an electrode of a coil shape wound along the outer peripheral surface of the process vessel.

15. A reflector used in a substrate processing apparatus comprising: a process vessel defining a process chamber; a process gas supplier configured to supply a process gas into the process vessel; an electromagnetic field generation electrode extending along an outer peripheral surface of the process vessel while being spaced apart from the outer peripheral surface of the process vessel and configured to generate an electromagnetic field in the process vessel by being supplied a high frequency power; and a heater configured to radiate an infrared light to heat a substrate accommodated in the process chamber,
wherein the reflector is provided between the process vessel and the electromagnetic field generation electrode and configured to reflect the infrared light radiated from the heater.

16. A method of manufacturing a semiconductor device, comprising:
(a) loading a substrate into a process chamber of a substrate processing apparatus comprising:
a process vessel defining the process chamber;
an electromagnetic field generation electrode extending along an outer peripheral surface of the process vessel while being spaced apart from the outer peripheral surface of the process vessel;
a heater configured to radiate an infrared light; and
a reflector provided between the process vessel and the electromagnetic field generation electrode and configured to reflect the infrared light radiated from the heater;
(b) heating the substrate accommodated in the process chamber by the infrared light radiated by the heater;
(c) supplying a process gas into the process vessel;
(d) plasma-exciting the process gas by supplying a high-frequency power to the electromagnetic field generation electrode to generate the electromagnetic field in the process vessel; and
(e) processing the substrate with the plasma-excited process gas.
